(19) United States
(12) Patent Application Publication
(10) Pub. No.: US 2026/0242948 A1
(43) Pub. Date: Aug. 20, 2026

(54) THIN FILM FORMING MATERIAL, METHOD OF FORMING THIN FILM, AND SEMICONDUCTOR SUBSTRATE AND SEMICONDUCTOR DEVICE FABRICATED USING THE SAME

(71) Applicant: SOULBRAIN CO., LTD., Gyeonggi-do (KR)

(72) Inventors: Jae Sun JUNG, Gyeonggi-do (KR); Chang Bong YEON, Gyeonggi-do (KR); Ji Hyun NAM, Gyeonggi-do (KR); Deok Hyun CHO, Gyeonggi-do (KR)

(21) Appl. No.: 19/159,342

(22) PCT Filed: Feb. 22, 2024
(86) PCT No.: PCT/KR2024/002327

§ 371 Date: Aug. 25, 2025

(30) Foreign Application Priority Data
Feb. 23, 2023 (KR) 10-2023-0024371
Apr. 12, 2023 (KR) 10-2023-0048191
Oct. 31, 2023 (KR) 10-2023-0147439
Feb. 22, 2024 (KR) 10-2024-0025544

(51) Int. Cl. C23C 16/455; C23C 16/18; C23C 16/34; C23C 16/44; H10P 14/43

(52) U.S. Cl. CPC C23C 16/45553; C23C 16/18; C23C 16/34; C23C 16/4408; H10P 14/43

(57) ABSTRACT

The present invention relates to a thin film forming material, a method of forming a thin film, and a semiconductor substrate and semiconductor device fabricated using the same. According to the present invention, by applying a predetermined material capable of forming a metal thin film or a metal nitride thin film through a reduction or catalytic reaction as a thin film forming material, a thin film having low resistivity may be effectively manufactured. In addition, impurities of the thin film caused by ligands such as carbon may be reduced, and thin film properties such as resistivity and crystallinity may be improved.

### TECHNICAL FIELD

The present invention relates to a thin film forming material, a method of forming a thin film and a semiconductor substrate and semiconductor device fabricated using the same. According to the present invention, by applying a predetermined material capable of forming a metal thin film or a metal nitride thin film through a reduction or catalytic reaction as a thin film forming material, a thin film having low resistivity may be effectively manufactured. In addition, impurities of the thin film caused by ligands such as carbon may be reduced, and thin film properties such as roughness and crystallinity may be improved.

### BACKGROUND ART

As the performance sophistication and high integration degree of semiconductor devices are required, electrode materials or diffusion barrier materials with reduced resistivity are demanded.

These materials are provided in the form of thin films through an atomic layer deposition (ALD) process, and in the reduction process used for forming the thin film, either a very strong reducing agent or high thermal energy is required.

However, very strong reaction n gas such as N₂H₄ hydrazine are highly toxic and hazardous, resulting in handling issues, and high heat energy is required for reduction to H₂. When high thermal energy is applied, the precursor compound may undergo thermal decomposition, so that in highly integrated substrates or substrates with high aspect ratios and complex structures, step coverage may deteriorate, or voids and seams may occur.

In addition, impurities (C, Cl⁻, F⁻, etc.) derived from the ligands of the precursor compound may be introduced into the thin film, thereby not only contaminating the thin film but also disturbing the crystal arrangement, which reduces the density of the formed thin film, and thus may cause conductivity degradation problems attributable to low density.

Therefore, there is a need to develop a thin film forming material capable of forming a uniform thin film with a complex structure, having excellent thin film properties such as crystallinity, reducing the residual amount of thin film impurities caused by ligands such as carbon, and providing a thin film with low resistivity; a method of forming a thin film using the thin film forming material; and a semiconductor substrate fabricated using the thin film forming material.

### RELATED ART DOCUMENTS

### Patent Documents

KR 2000-0022014 A

### DISCLOSURE

### Technical Problem

Therefore, the present invention has been made in view of the above problems, and it is one object of the present invention to provide a method of forming a thin film and a semiconductor substrate fabricated using the same. According to the method of the present invention, by applying a novel material that forms a metal thin film or metal nitride thin film through a reduction or catalytic reaction as a thin film forming material, impurities may be reduced and resistivity may be improved, thereby effectively improving the thin film and deposition characteristics, so that even when a thin film is formed on a substrate having a complex structure, a thin film having uniform thickness and low resistivity may be provided.

It is another object of the present invention to improve film quality such as electrical characteristics and thin film density by applying a novel material that forms a metal thin film or metal nitride thin film through a reduction or catalytic reaction as a thin film forming material.

It is yet another object of the present invention to provide a thin film having low resistivity by applying a novel material that forms a metal thin film or metal nitride thin film through a reduction or catalytic reaction as a thin film forming material.

The above and other objects can be accomplished by the present invention described below.

### Technical Solution

In accordance with one aspect of the present invention, provided is a thin film forming material having a bond dissociation energy of 242 kJ/mol or less and 290 kJ/mol or more with hydrogen (H), carbon (C), or a halogen element (F, Cl, or Br) bonded to iodine as calculated using a Gaussian 16 program (basis set of DFT-D3/B3LYP (iodine, metal: LanL2DZ, other elements such as carbon and hydrogen: 6−31+G (d.p)).

Preferably, the thin film forming material according to the present invention may have a bond dissociation energy of 300 to 350 kJ/mol or 150 to 242 kJ/mol with hydrogen (H), carbon (C), or a halogen element (F, Cl, or Br) bonded to iodine as calculated using a Gaussian 16 program (basis set off DFT-D3/B3LYP (iodine, metal: LanL2DZ, other elements such as carbon and hydrogen: 6−31+G (d.p)).

The thin film forming material may be a material that forms a metal thin film or a metal nitride thin film through a reduction or catalytic reaction, and may include a compound in which iodine (I) is bonded to hydrogen (H), carbon (C), or a halogen element (F, Cl, or Br).

The thin film forming material may include one or more selected from compounds represented by Chemical Formulas 1-1 to 1-11 below.

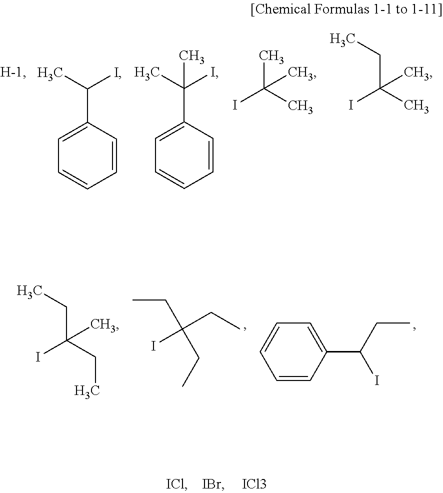

The thin film forming material may be 3 N to 15 N hydrogen iodide, a gas mixture containing 1 to 99% by weight of 3 N to 15 N hydrogen iodide and a residual amount (amount that makes a total amount 100% by weight) of an inert gas, or an aqueous solution mixture containing 0.5 to 70% by weight of 3 N to 15 N hydrogen iodide and a residual amount (amount that makes a total amount 100% by weight) of water. Here, the inert gas may be nitrogen, helium, or argon having a purity of 4 N to 9 N. In this case, a metal thin film or metal nitride thin film having low resistivity may be effectively formed through a reduction or catalytic reaction.

In accordance with another aspect of the present invention, provided is a method of forming a thin film using the thin film forming material described above.

For example, the method of forming a thin film may include injecting a precursor compound into a chamber to adsorb the precursor compound onto a surface of a substrate; and injecting the thin film forming material into the chamber and forming a metal thin film or a metal nitride thin film through a reduction reaction.

As another example, the method of forming a thin film may include injecting a precursor compound into a chamber to adsorb the precursor compound onto a surface of a substrate; injecting the thin film forming material into the chamber to reduce reaction activation energy with a reaction gas; and supplying a reaction gas into the chamber and forming a metal thin film or a metal nitride thin film through a reduction reaction.

Each step may include purging the inside of the chamber with a purge gas.

The chamber may be an ALD chamber, a CVD chamber, a PEALD chamber, or a PECVD chamber.

The thin film may be a laminated film containing one or more selected from the group consisting of Al, Cu, Au, Mo, Ag, W, Pt, Ta, Co, Ru, Rh, and Ti.

The metal thin film or metal nitride thin film may be a thin film having a resistivity of 5 μΩ·cm to 1000 μΩ·cm.

The thin film may be a wiring thin film or a diffusion barrier film.

The wiring thin film may be a metal thin film of Mo, W, Ru, Cu, or Rh.

The diffusion barrier film may be a metal nitride thin film of MON, WN, TiN, or TaN.

The metal thin film or metal nitride thin film may be provided as a precursor compound for a thin film having low resistivity.

The precursor compound may be a molecule having Al, Cu, Au, Mo, Ag, W, Pt, Ta, Co, Ru, Rh, and Ti as a central metal atom (M) and having one or more ligands selected from C, N, O, H, and X (halogen), and may have a bond dissociation energy of 350 kJ/mol or less between the central metal atom and the ligands as calculated using a Gaussian 16 program (basis set of DFT-D3/B3LYP (central metal, iodine: LanL2DZ, C, N, O, H, X: 6−31+G (d.p)).

The precursor compound may be a molecule composed of one or more selected from the group consisting of Al, Cu, Au, Mo, Ag, W, Pt, Ta, Co, Ru, and Ti, and may be a compound having a vapor pressure of more than 0.01 mTorr and 100 Torr or less at 25° C.

The substrate loaded into the chamber may be heated to 100 to 800° C.

The reaction gas may be ammonia or hydrogen, and in the case of a noble metal, the reaction gas may also be oxygen.

The thin film may be an aluminum metal film, a copper metal film, a gold metal film, a molybdenum metal film, a silver metal film, a tungsten metal film, a platinum metal film, a tantalum metal film, a cobalt metal film, a ruthenium metal film, a rhodium metal film, a titanium metal film, an aluminum nitride film, a copper nitride film, a gold nitride film, a molybdenum nitride film, a silver nitride film, a tungsten nitride film, a platinum nitride film, a tantalum nitride film, a cobalt nitride film, a ruthenium nitride film, a rhodium nitride film, or a titanium nitride film.

The thin film is characterized by having a low resistivity of 5 μΩ·cm to 1000 μΩ·cm.

The thin film is characterized in that, when the content of thin film impurities derived from ligands is measured by XPS or SIMS, impurities caused by ligands such as carbon are 1% or less.

The thin film is characterized in that crystallinity measured by XRD is improved due to the effect of reducing impurities inside the thin film through stronger reduction of the metal precursor.

In accordance with still another aspect of the present invention, provided is a semiconductor substrate fabricated using the method of forming a thin film described above.

The thin film may be a multilayer structure of 2 or 3 layers.

In accordance with yet another aspect of the present invention, provided is a semiconductor device including the semiconductor substrate described above.

### Advantageous Effects

According to the present invention, the present invention has an effect of providing a method of forming a thin film. According to the method of the present invention, by applying a predetermined material capable of serving as a catalyst or reducing agent as a thin film forming material, a reduction or catalytic reaction (reduction of the reaction activation energy with the reaction gas) can be performed at a process temperature at which a precursor is not thermally decomposed. Thus, even when forming a thin film on a substrate having a highly integrated or complex structure, a uniform thin film can be formed, and impurities and film quality can be improved, thereby providing a high-quality thin film.

In addition, by more effectively reducing thin film impurities such as carbon derived from ligands and process by-products that cause deterioration of film properties such as crystallinity and electrical characteristics during thin film formation, film quality can be modified to improve the crystallinity and resistivity of a thin film, thereby enhancing the electrical characteristics of the thin film. In addition the present invention has an effect of providing a method of forming a thin film and a semiconductor substrate fabricated using the same.

### DESCRIPTION OF DRAWINGS

FIG. 1 is a graph showing the AES analysis results according to temperature in Example 5 of the present invention.

FIG. 2 is an XRD analysis graph according to process temperature for Example 5 of the present invention and conventional Comparative Example 3.

FIG. 3 is an XRD analysis graph in Example 6 of the present invention and conventional Comparative Example 4.

FIGS. 4 and 5 are diagrams respectively showing, in

Example 8 and Comparative Example 5, the reaction activation energy required to reduce the co ligand of the Mo(CO)₆ precursor and the NO ligand of the (EtCp)Mo(CO)₂(NO) precursor, compared between H₂ and HI.

### BEST MODE

Hereinafter, a method of forming a thin film according to the present invention and a semiconductor substrate fabricated using the method are described in detail.

In the present disclosure, the term “thin film forming material” refers to a novel material capable of forming a metal thin film and a metal nitride thin film through a catalytic reaction or a reduction reaction.

In the present disclosure, unless otherwise specified, the term “catalytic reaction” refers to a reaction accompanied by an effect of reducing the reaction activation energy with a reaction gas (a reaction that substitutes or partially reduces the ligands of a precursor compound), and may subsequently involve a reduction process using a reaction gas.

In the present disclosure, unless otherwise specified, the term “reduction reaction” refers not only to a reaction that substitutes the ligands of a precursor compound, but also to a reaction that reduces to such an extent as to omit the reduction reaction provided by a conventional reaction gas.

In the present disclosure, unless otherwise specified, the term “modification” refers to the positive interaction of a substance other than a precursor and reactant on a reaction surface to improve film quality, such as reducing resistivity, increasing density, and reducing impurities, in a deposited thin film.

In the present disclosure, unless otherwise specified, % refers to % by weight.

The present inventors confirmed that, when a predetermined thin film forming material capable of performing a catalytic reaction or reducing agent at a relatively low process temperature at which a precursor is not thermally decomposed was used for a precursor compound adsorbed on the surface of a substrate loaded inside a chamber, it was confirmed that film quality such as electrical characteristics and crystallinity was improved while preventing and suppressing the introduction of thin film impurities caused by ligands such as carbon. Based on these results, the present inventors conducted further studies to complete the present invention.

For example, the thin film may be provided with one or more precursors selected from the group consisting of Al, Cu, Au, Mo, Ag, W, Pt, Ta, Co, Ru, Rh, and Ti, and may provide a metal nitride thin film, or a metal thin film. In this case, the effects to be achieved by the present invention may be sufficiently obtained.

As a specific example, the thin film may have a film composition including an aluminum metal film, a copper metal film, a gold metal film, a molybdenum metal film, a silver metal film, a tungsten metal film, a platinum metal film, a tantalum metal film, a cobalt metal film, a ruthenium metal film, a rhodium metal film, a titanium metal film, an aluminum nitride film, a copper nitride film, a gold nitride film, a molybdenum nitride film, a silver nitride film, a tungsten nitride film, a platinum nitride film, a tantalum nitride film, a cobalt nitride film, a ruthenium nitride film, a rhodium nitride film, or a titanium nitride film.

The thin film may include the above-described film composition alone or a selective area, but is not limited thereto, and may also include SiH, SiOH, and the like.

The thin film may be a laminated film containing one or more selected from the group consisting of Al, Cu, Au, Mo, Ag, W, Pt, Ta, Co, Ru, Rh, and Ti.

The thin film may be utilized in a semiconductor device for purposes such as a commonly used wiring thin film or diffusion barrier film, as well as a thin film having low resistivity.

The resistivity of the thin film may be in the range of 5 μΩ·cm to 1000 μΩ·cm.

The wiring thin film may be a metal thin film of Mo, W, Ru, Cu, or Rh.

The diffusion barrier film may be a metal nitride thin film of MON, WN, TiN, or TaN.

The metal thin film or metal nitride thin film may be provided with a precursor compound for a thin film having low resistivity.

For example, the precursor compound may have Al, Cu, Au, Mo, Ag, W, Pt, Ta, Co, Ru, Rh, or Ti as a central metal atom (M), and may have a structure in which ligands (L1, L2, L3, L4, L5, L6, etc.) are bonded.

As a specific example, the precursor compound may be a molecule having Al, Cu, Au, Mo, Ag, W, Pt, Ta, Co, Ru, Rh, and Ti as a central metal atom (M) and having one or more ligands selected from C, N, O, H, and X (halogen). In the case of a precursor having a vapor pressure of 0.01 mTorr to 100 Torr at 25° C., the effect of using the thin film forming material may be maximized.

As another specific example, the precursor compound may be a molecule having Al, Cu, Au, Mo, Ag, W, Pt, Ta, Co, Ru, Rh, and Ti as a central metal atom (M) and having one or more ligands selected from C, N, O, H, and X (halogen), and may be a compound having a bond dissociation energy of 350 kJ/mol or less between the central metal atom and the ligands as calculated using a Gaussian 16 program (basis set of DFT-D3/B3LYP (central metal, iodine: LanL2DZ, C, N, O, H, X: 6-31+G (d.p)).

For example, when the central metal is divalent, L1 and L2 may be attached to the central metal as ligands. When the central metal is hexavalent, L1, L2, L3, L4, L5, and L6 may be attached to the central metal. The ligands corresponding to L1 to L6 may be the same or different.

For example, L1, L2, L3, L4, L5, and L6 may be the same or different as —H or —R, where —R may be a C1-C10 alkyl, a C1-C10 alkene, or a C1-C10 alkane, and may be linear or cyclic, and depending on the oxidation state of the central metal, the number n of L in L1, L2, L3, and L4 may be from 2 to 6.

For example, when the central metal is divalent, L1 and L2 may be attached to the central metal as ligands. When the central metal is hexavalent, L1, L2, L3, L4, L5, and L6 may be attached to the central metal. The ligands corresponding to L1 to L6 may be the same or different.

As a specific example, L1, L2, L3, L4, L5, and L6 may be the same or different as —H, —OR, or —NR₂, where-R may be H, a C1-C10 alkyl, a C1-C10 alkene, a C1-C10 alkane, iPr, or tBu. In this case, an appropriate reaction energy to be substituted by a reaction gas described later may be obtained.

As a specific example, L1, L2, L3, L4, L5, and L6 may be the same or different as —H or —X, where —X may be F, Cl, Br, or I. In this case, an appropriate reaction energy to be substituted by a reaction gas described later may be obtained. As a specific example, L1, L2, L3, L4, L5, and L6 may

be the same or different as —H or —R, where —R may be a C1-C10 alkyl, a C1-C10 alkene, or a C1-C10 alkane, and may have a linear or cyclic structure. In this case, an appropriate reaction energy to be substituted by a reaction gas described later may be obtained.

As a specific example, L1, L2, L3, L4, L5, and L6 may be the same or different as —H, —OR, or —NR₂, where-R may be H, a C1-C10 alkyl, a C1-C10 alkene, a C1-C10 alkane, iPr, or tBu. In this case, an appropriate reaction energy to be substituted by a reaction gas described later may be obtained.

As a specific example, L1, L2, L3, L4, L5, and L6 may be the same or different as —H or —X, where —X may be F, Cl, Br, or I. In this case, an appropriate reaction energy to be substituted by a reaction gas described later may be obtained.

Specifically, the precursor compound having molybdenum (Mo) as a central metal may be at least one selected from compounds having structures represented by Chemical Formulas 2 and 3 below, and may include a trimethylene methane ligand and a derivative thereof, without being limited thereto.

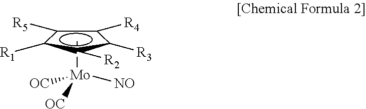

(In Chemical Formula 2, R1 to R5 are independently selected from hydrogen, an amino group, a silyl group, a C1-C8 alkyl group, and a C6-C8 aryl group, and the case where R1 to R5 are all hydrogen at the same time is excluded.)

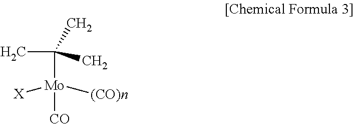

(In Chemical Formula 3, X includes H; F; Cl; Br; I; NO; CN; amidinate; guanidinate; ethylenediamine; propylenediamine; —NR6R7; —OR8; R9Cp; and a linear, branched, or cyclic, saturated or unsaturated hydrocarbon substituted with one or more of carbon (C), nitrogen (N), oxygen (O), phosphorus (P), and sulfur(S), R6, R7, R8, and R9 are independently selected from hydrogen, a C1-C12 alkyl group, and a C6-C12 aryl group, and n is an integer of 0 to 2.)

For example, the derivative of the trimethylene methane ligand may include a structure having a tribenzylidene methane ligand, a dibenzylidene methane ligand, and the like.

For example, the precursor compound having molybdenum (Mo) as a central metal may be Mo(CO)₆, (ethylbenzene)₂Mo, (2, 6-diisopropylaniline)Mo(CO)₃, (1,4-diisopropyl-1, 4-diazabutadiene)Mo(CO), Mo(CO)₅PCl₂Me, molybdenum acetate dimer, (ethylbenzene)Mo(allyl)₂, MeCpMo(CO)₂ (allyl), iprCpMo(CO)₂ (allyl), Mo(thd)₃, (MeCp)Mo(EMA)₃, (tert-butylimido)Mo(MeCp)₂, TDMAMO, Cp2MoH2, Mo(dithiocabate)₄, (tert-butylimido)₂MoCl (aminothiolate), (tert-butylimido)₂Mo(tert-butylthiol)(aminothiolate), (tertbutylimido)₂Mo(aminothiolate)₂, (tert-butylimido)₂Mo(tert-butylthiol)₂, (tert-butylimido)₂Mo(tert-butylamine)₂, (tert-butylimido)₂Mo(CpEMA), MoO₂(ipr-amidinate)₂, (tert-butylimido)₂Mo(ipr-amidinate)₂, (tert-butylimido)₂Mo(tert-butoxy)₂, (tert-butylimido)₂Mo(N, N-dimethyldiethylene triamine), (tert-butylimido)₂Mo (hydrazido) Cl, MoO₂(dithiocarbamate)₂, (1,4-ditert-butyl-1, 4, diazabutadiene)Mo(tert-butylimido)₂, MoO₂Cl₂, or the like.

Here, MoO₂Cl₂, (ethylbenzene)₂Mo, (2,6-diisopropylaniline)Mo(CO)₃, (benzene)Mo(CO)₃, and 1,4-diisopropyl-1, 4-diazabutaiene)Mo(CO)₃ are compounds represented by Chemical Formulas 4-1 to 4-5 below, respectively.

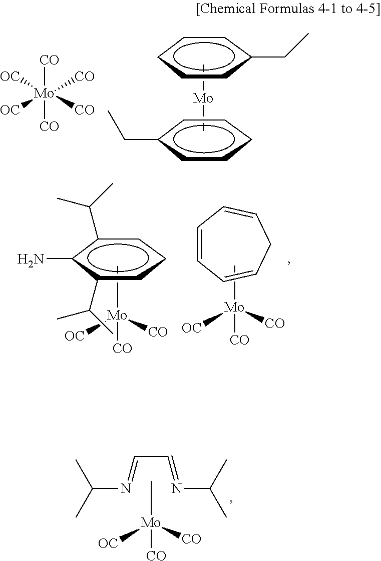

Here, tMo(CO)₅PCl₂Me, molybdenum acetate dimer, (ethylbenzene)Mo(allyl)₂, and MeCpMo(CO)₂ (allyl), iprCpMo(CO)₂ (allyl) are compounds represented by Chemical Formulas 4-6 to 4-10 below, respectively.

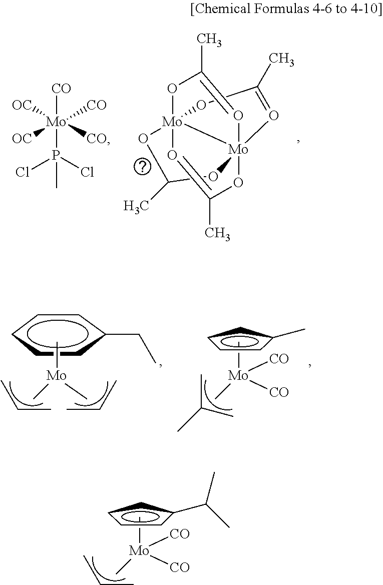

Here, Mo(thd)₃, (MeCp)Mo(EMA)₃, (tert-butylimido) Mo (MeCp)₂, TDMAMo, and Cp2MoH2 are compounds represented by Chemical Formulas 4-11 to 4-15 below, respectively.

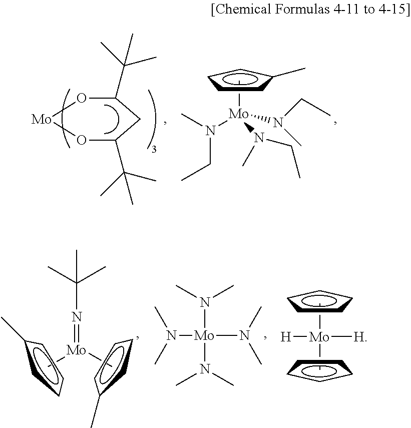

Here, Mo(dithiocabate)₄, (tert-butylimido)₂MoCl (aminothiolate), (tert-butylimido)₂Mo(tert-butylthiol)(aminothiolate), (tertbutylimido)₂Mo(aminothiolate)₂, and (tert-butylimido)₂Mo(tert-butylthiol)₂ are compounds represented by Chemical Formulas 4-16 to 4-20 below, respectively.

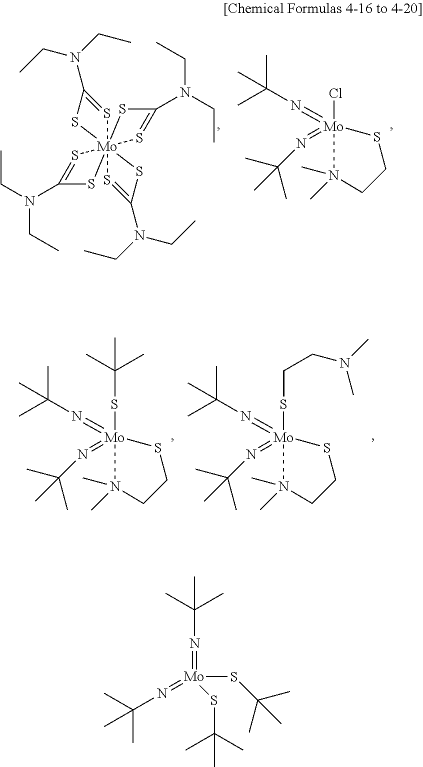

Here, (tert-butylimido)₂Mo(tert-butylamine)₂, (tert-butylimido)₂Mo(CpEMA), MoO₂(ipr-amidinate)₂, and (tert-butylimido)₂Mo(ipr-amidinate)₂ are compounds represented by Chemical Formulas 4-20 to 4-24 below, respectively.

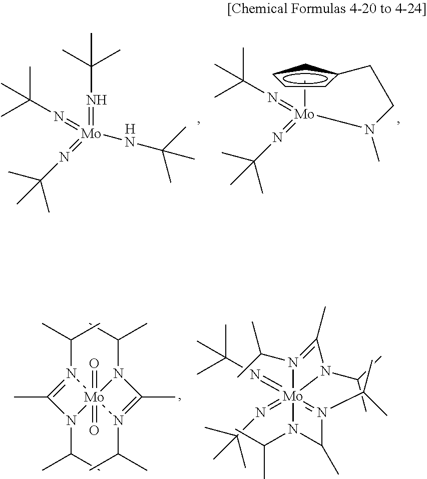

Here, (tert-butylimido)₂Mo(tert-butoxy)₂, (tert-butylimido)₂Mo(N, N-dimethyldiethylene triamine), (tert-butylimido)₂Mo(hydrazido) Cl, MoO₂(dithiocarbamate)₂, 1,4-ditert-butyl-1, 4, diazabutadiene)Mo(tert-butylimido)₂, MoO₂Cl₂, (tert-butylimido)₂Mo(dimethylamide)₂, and (methylbenzene)₂MO are compounds represented by Chemical Formulas 4-25 to 4-31 below, respectively.

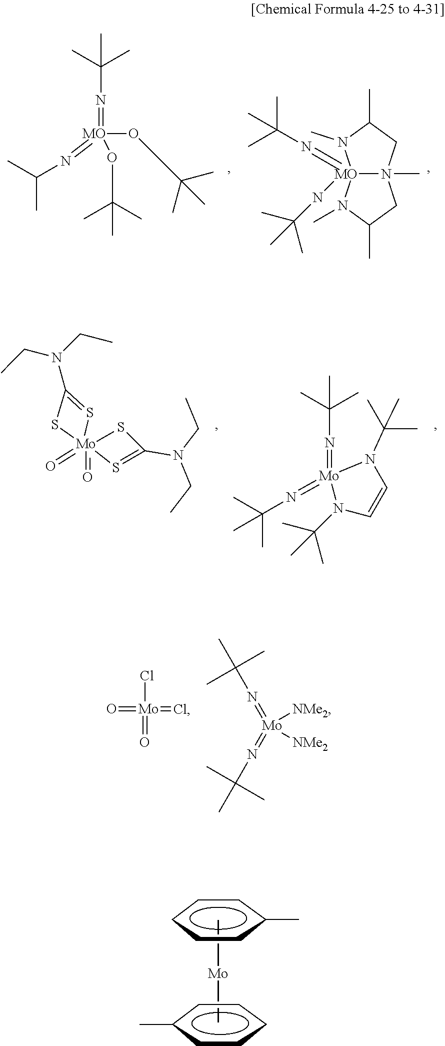

For example, the precursor compound may be mixed with a non-polar solvent and used. In this case, the viscosity or vapor pressure of the precursor compound may be easily controlled.

The thin film forming material of the present invention may perform a catalytic reaction that lowers the activation energy of the precursor compound adsorbed on the substrate to effectively substitute ligands, and depending on the structure thereof, may also possess reducing power to perform a reduction reaction, thereby eliminating the need for a reduction process using a reaction gas required in a subsequent process after the catalytic reaction.

For example, the substitution of the ligands may be performed on the entire substrate or a part of the substrate where the thin film is formed by using the thin film forming material, or, when necessary, a reaction gas described later.

The thin film forming material may be a material used to form a metal thin film or a metal nitride thin film, and for example, may include a compound in which iodine (I) is bonded to hydrogen (H), carbon (C), or a halogen element (F, Cl, or Br).

The reaction forming material may perform a reduction or catalytic reaction to form a metal thin film or a metal nitride thin film.

The thin film forming material may have a total bond dissociation energy of 242 kJ/mol or less or 290 kJ/mol or more as calculated using a Gaussian 16 program (basis set of DFT-D3/B3LYP (iodine: LanL2DZ, other elements such as carbon and hydrogen: 6−31+G (d.p)). In this case, the content of thin film impurities caused by ligands such as carbon may be reduced, and a thin film having low resistivity may be effectively provided.

Among the thin film forming materials, in the case of iodine compounds bonded with carbon or halogen elements (F, Cl, Br), a reduction effect may be exhibited, and the appropriate bond dissociation energy of carbon and iodine to prevent carbon impurities from remaining may be 242 kJ/mol or less.

In the present invention, iodine compounds bonded with hydrogen that exhibit the desired effect may have a bond dissociation energy of 290 kJ/mol or more.

The thin film forming material may include one or more selected from compounds represented by Chemical Formulas 1-1 to 1-11 below.

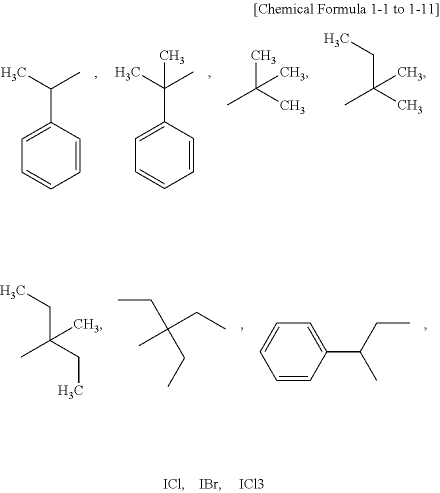

For example, the thin film forming material may be 3 N to 15 N hydrogen iodide, a gas mixture containing 1 to 99% by weight of 3 N to 15 N hydrogen iodide and a residual amount (amount that makes a total amount 100% by weight) of an inert gas, or an aqueous solution mixture containing 0.5 to 70% by weight of 3 N to 15 N hydrogen iodide and a residual amount (amount that makes a total amount 100% by weight) of water. Here, the inert gas may be nitrogen, helium, or argon having a purity of 4 N to 9 N. In this case, a reduction or catalytic reaction may be performed to reduce impurities, and a metal thin film or metal nitride thin film having low resistivity may be effectively formed.

Preferably, the thin film forming material is 5 N to 6 N hydrogen iodide, a gas mixture containing 1 to 99% by weight of 5 N to 6 N hydrogen iodide and a residual amount (amount that makes a total amount 100% by weight) of an inert gas, or an aqueous solution mixture containing 0.5 to 70% by weight of 5 N to 6 N hydrogen iodide and a residual amount (amount that makes a total amount 100% by weight) of water. Here, the inert gas may be nitrogen, helium, or argon having a purity of 4 N to 9 N. In this case, side reactions may be suppressed during thin film formation, and thin film growth rate may be adjusted to reduce process by-products in a thin film, thereby reducing corrosion or deterioration and improving the crystallinity and film quality of a thin film. In addition, even when forming a thin film on a substrate having a highly integrated or complex structure, the thickness uniformity of a thin film may be greatly improved.

In this case, by sufficiently providing an effect according to a catalytic reaction or a reduction reaction to the precursor compound adsorbed on the substrate at a relatively low process temperature at which a precursor is not thermally decomposed, when a thin film is formed on a substrate having a highly integrated or complex structure, the thickness uniformity of a thin film may be greatly improved. In addition to the thin film precursor, process by-products may be prevented from being adsorbed, thereby effectively protecting the surface of the substrate. In addition, the reaction rate may be reduced, and process by-products may be effectively removed.

The thin film forming material may be preferably a compound having a purity of 99.9% or more, 99.95% or more, or 99.99% or more. For reference, when a compound having a purity of less than 99% is used, impurities may remain in a thin film or cause side reactions with precursors or reactants. Accordingly, it is desirable to use a material having a purity of 99% or more.

For example, the thin film may contain a halogen compound in an amount of 100 ppm or less. For reference, when halogen excessively remains, when a nitriding agent described later is used under a temperature condition of 200 to 300° C., a chloride such as NH₄Cl may be generated and remain in the thin film, which is undesirable.

The thin film may be used as a diffusion barrier film or a wiring thin film, without being limited thereto.

In particular, as a relatively coarse thin film is formed, the growth rate of a thin film formed at the same time is greatly reduced, so that even when applied to a substrate having a complex structure, the uniformity of the thin film may be secured, and the thin film may be deposited in a thin thickness. In addition, the remaining amounts of 0, Si, metals, and metal oxides remaining as process by-products may be improved. In addition, even the remaining amount of carbon, which was difficult to reduce in the past, may be improved.

The method of forming a thin film according to one embodiment of the present invention includes a step of injecting a precursor compound into a chamber to adsorb the precursor compound onto the surface of a substrate; and a step of injecting the thin film forming material into the chamber and forming a metal thin film or a metal nitride thin film through a reduction reaction. In this case, the reduction of the precursor adsorbed on the substrate may be effectively performed at a relatively low process temperature at which the precursor is not thermally decomposed, thereby appropriately reducing the thin film growth rate. Thus, even in the case of forming a thin film on a substrate having a highly integrated or complex structure, the uniformity of the thin film may be greatly improved, and a thin film having low resistivity may be provided.

The thin film forming material and precursor compound may be transferred into the chamber by a VFC method, a DLI method, or an LDS method.

The input amount (mg/cycle) ratio of the precursor compound to the thin film forming material in the chamber may be 1:1 to 1:20.

In the step of injecting the thin film forming material onto the surface of the substrate, the feeding time (sec) per cycle of the thin film forming material onto the surface of the substrate may be preferably 0.01 to 10 seconds, more preferably 0.02 to 8 seconds, still more preferably 0.04 to 6 seconds, still more preferably 0.05 to 4 seconds. Within this range, the thin film growth rate may be reduced, and step coverage and cost efficiency may be excellent.

In the present disclosure, the feeding time of the thin film forming material is based on a flow rate of 0.1 to 8,000 mg/cycle for a chamber volume of 15 to 20 L, more specifically, on a flow rate of 10 to 5,000 mg/cycle for a chamber volume of 18 L.

As a specific example, the method of forming a thin film may include a step of injecting a precursor compound into a chamber to adsorb the precursor compound onto the surface of a substrate; a step of performing first purging of the inside of the chamber with a purge gas; a step of injecting the above-described thin film forming material into the chamber to introduce an adsorbed precursor compound and forming a metal thin film or a metal nitride thin film through a reduction reaction; and a step of performing second purging of the inside of the chamber with a purge gas.

The entire steps described above may be defined as a unit cycle (cycle), and the cycle may be repeatedly performed until a thin film having a desired thickness is obtained. In this way, when the thin film forming material is sequentially introduced after the precursor compound within one cycle to improve the film quality, the generated process by-products may be effectively removed, thereby reducing the resistivity of the thin film, greatly improving step coverage, and enhancing the uniformity of the thin film. In addition, film quality such as electrical characteristics, dielectric properties, and thin film density may be improved, and a thin film having low resistivity may be provided.

The chamber may be an ALD chamber, a CVD chamber, a PEALD chamber, or a PECVD chamber.

The substrate loaded into the chamber may be heated to 100 to 800° C.

The thin film forming material or precursor compound may be vaporized and injected, followed by a plasma post-treatment step. In this case, process by-products may be reduced while improving the growth rate of the thin film.

The method of forming a thin film according to another embodiment of the present invention includes a step of injecting a precursor compound into a chamber to adsorb the precursor compound onto the surface of a substrate; a step of injecting a thin film forming material into the chamber and forming a deposition film through a catalytic reaction; and a step of injecting a reaction gas into the chamber to form a nitride film. In this case, the reduction of the precursor adsorbed on the substrate may be effectively performed, thereby appropriately reducing the thin film growth rate. Thus, even in the case of forming a thin film on a substrate having a highly integrated or complex structure, film quality such as electrical characteristics and thin film density may be greatly improved.

As a specific example, the method of forming a thin film may include a step of injecting a precursor compound into a chamber to adsorb the precursor compound onto the surface of a substrate; a step of performing first purging of the inside of the chamber with a purge gas; a step of injecting the above-described thin film forming material into the chamber to form a deposition film through a catalytic reaction; a step of performing second purging of the inside of the chamber with a purge gas; a step of injecting a reaction gas into the chamber to form a thin film; and a step of performing third purging of the inside of the chamber with a purge gas.

The entire steps described above may be defined as a unit cycle (cycle), and the cycle may be repeatedly performed until a thin film having a desired thickness is obtained. In this way, when the thin film forming material and the precursor compound are sequentially introduced within one cycle to improve the film quality, process by-products may be greatly reduced, and step coverage may be greatly improved. In addition, the crystallinity of the thin film may be increased, thereby reducing the resistivity of the thin film. In addition, even when applied to a semiconductor device having a high aspect ratio, the thickness uniformity of a thin film may be greatly improved, thereby ensuring the reliability of the semiconductor device. In addition, film quality such as electrical characteristics and thin film density may be improved, and a thin film having low resistivity may be provided.

The chamber may be an ALD chamber, a CVD chamber, a PEALD chamber, or a PECVD chamber.

The substrate loaded into the chamber may be heated to 100 to 800° C.

The reaction gas is not limited as long as the reaction gas is a gas used for producing a metal thin film or a metal nitride thin film, and may, for example, be nitrogen, ammonia, or hydrogen.

In the present disclosure, the feeding time of the reaction gas is based on a flow rate of 0.1 to 8,000 mg/cycle for a chamber volume of 15 to 20 L, more specifically, on a flow rate of 10 to 5,000 mg/cycle for a chamber volume of 18 L.

In the step of purging the unadsorbed precursor compound, the amount of purge gas injected into the ALD chamber is not particularly limited as long as the amount is sufficient to remove the unadsorbed precursor compound. For example, the amount may be 10 to 10,000 times, preferably 50 to 50,000 times, more preferably 100 to 10,000 times the volume of the precursor compound injected into the chamber. Within this range, by sufficiently removing the unadsorbed precursor compound, a thin film may be formed evenly and deterioration of film quality may be prevented. Here, the input amounts of the purge gas and precursor compound are each based on one cycle, and the volume of the precursor compound refers to the volume of the vaporized precursor compound vapor.

In addition, in the purging step performed immediately after the reaction gas supply step, the amount of purge gas introduced into the ALD chamber may be, for example, 10 to 10,000 times, preferably 50 to 50,000 times, more preferably 100 to 10,000 times the volume of reaction gas introduced into the ALD chamber. Within this range, the desired effects may be sufficiently achieved. Here, the input amounts of the purge gas and reaction gas are based on one cycle.

The thin film forming material, precursor compound, and reaction gas may preferably be transferred into the ALD chamber by a VFC method, a DLI method, or an LDS method, and more preferably, by a VFC method.

For example, the substrate loaded into the chamber may be heated to 100 to 800° C., as a specific example, 300 to 600° C. The thin film forming material or precursor compound may be injected onto the substrate in an unheated or heated state, or may be injected unheated and then heated during the deposition process, depending on the deposition efficiency. For example, the thin film forming material or precursor compound may be injected onto the substrate at 50 to 400° C. for 1 to 20 seconds.

The input amount (mg/cycle) ratio of the precursor compound to the thin film forming material in the chamber may be preferably 1:1 to 1:400, more preferably 1:2 to 1:350, still more preferably 1:2 to 1:300, still more preferably 1:2.5 to 1:200. Within this range, step coverage may be improved, and process by-products may be greatly reduced.

For example, the method of forming a thin film may be performed at a deposition temperature of 100 to 800° C., preferably 300 to 600° C., more preferably 300 to 500° C., still more preferably 300 to 400° C. Within this range, a thin film with excellent film quality may be grown while implementing ALD process characteristics.

For example, the method of forming a thin film may be performed at a deposition pressure of 0.01 to 20 Torr, preferably 0.1 to 20 Torr, more preferably 0.1 to 10 Torr, most preferably 0.3 to 7 Torr. Within this range, a thin film having a uniform thickness may be obtained.

In the present disclosure, the deposition temperature and the deposition pressure may be measured as temperature and pressure formed within the deposition chamber, or as temperature and pressure applied to the substrate within the deposition chamber.

The method of forming a thin film may preferably include a step of increasing the temperature inside the chamber to a deposition temperature before introducing the precursor compound into the chamber; and/or a step of performing purging by injecting an inert gas into the chamber before introducing the precursor compound into the chamber.

In the method of forming a thin film, the intensity (c/s) of residual impurities (carbon or halogen elements) in the thin film may be preferably 100,000 or less, more preferably 70,000 or less, still more preferably 50,000 or less, still more preferably 10,000 or less, as a preferred example, 5,000 or less, still more preferably 10 to 4,000, still more preferably 10 to 3,000 as measured using a thin film having a thickness of 100 Å according to SIMS. Within this range, the effect of preventing deterioration of crystallinity and electrical characteristics is excellent.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the thin film growth rate per cycle may be appropriately controlled. In addition, since deposition is performed as an atomic mono-layer or nearly an atomic mono-layer, the film quality may be improved.

In addition, as a thin film manufacturing device capable of providing the method of forming a thin film, the present invention may include a thin film manufacturing device including an ALD chamber, a first vaporizer for vaporizing a precursor compound, a first transport means for transferring the vaporized precursor compound into the ALD chamber, a second vaporizer for vaporizing a thin film forming material, a second transport means for transferring the vaporized thin film forming material into the ALD chamber, and a third transport means for transferring a reaction gas into the ALD chamber. Here, vaporizers and transport means commonly used in the technical field to which the present invention pertains may be used in the present invention without particular limitation.

As a specific example, the method of forming a thin film is explained. First, a substrate on which a thin film is to be formed is placed in a deposition chamber capable of atomic layer deposition.

The substrate may include a semiconductor substrate, such as a silicon substrate or a silicon oxide substrate.

The substrate may further have a conductive layer or an insulating layer formed on the upper portion thereof.

To deposit a thin film on a substrate placed in the deposition chamber, the above-described thin film forming material, precursor compound, or mixture of the precursor compound and a non-polar solvent are prepared, respectively.

Next, the prepared precursor compound or a mixture of the precursor compound and a non-polar solvent (hereinafter referred to as composition for forming a thin film) is injected into the vaporizer, is transformed into a vapor phase, is transferred into the deposition chamber, and is adsorbed on the substrate. Then, the unadsorbed precursor compound or mixture of the precursor compound and a non-polar solvent is purged.

The non-polar solvent may preferably include one or more selected from the group consisting of alkanes and cycloalkanes. In this case, an organic solvent with low reactivity and solubility and easy moisture management may be included. In addition, step coverage may be improved even when deposition temperature increases during thin film formation.

As a preferred example, the non-polar solvent may include a C1 to C10 alkane or a C3 to C10 cycloalkane, preferably a C3 to C10 cycloalkane. In this case, reactivity and solubility may be low and moisture management may be easy.

In the present disclosure, C1, C3, and the like indicate the number of carbon atoms.

The cycloalkane may preferably include C3 to C10 monocycloalkanes, and among the monocycloalkanes, cyclopentane is liquid at room temperature and has the highest vapor pressure, so cyclopentane is preferable in the vapor deposition process, but the present invention is not limited thereto.

For example, the non-polar solvent may have a solubility (25° C.) of 200 mg/L or less, preferably 50 to 400 mg/L, more preferably 135 to 175 mg/L in water. Within this range, the reactivity toward the precursor compound may be reduced, and moisture may be easily managed.

In the present disclosure, solubility may be measured without any particular limitation by a measurement method or standard commonly used in the technical field to which the present invention pertains. For example, solubility may be measured by the HPLC method using a saturated solution.

Based on a total weight of the precursor compound and the non-polar solvent, the non-polar solvent may be included in an amount of 5 to 95% by weight, more preferably 10 to 90% by weight, still more preferably 40 to 90% by weight, most preferably 70 to 90% by weight.

When the content of the non-polar solvent exceeds the above range, impurities may be generated, which may increase the resistance and impurities within a thin film. When the content of the organic solvent is less than the range, the effect of improving step coverage due to solvent addition and the effect of reducing impurities such as chloride (Cl) ions may be reduced.

Next, the prepared thin film forming material is injected into the vaporizer, is transformed into a vapor phase, is transferred into the deposition chamber, and is adsorbed. Then, the unadsorbed thin film forming material is purged.

In the present disclosure, for example, the thin film forming material and precursor compound may be delivered into the deposition chamber by vapor flow control (VFC) using mass flow control (MFC) or a liquid delivery system (LDS) using liquid mass flow control (LMFC), preferably a VFC method.

At this time, a mixed gas of one or more selected from the group consisting of argon (Ar), nitrogen (N₂), and helium (He) may be used as a carrier gas or dilution gas to move the thin film forming material and precursor compound onto the substrate, without being limited thereto.

In the present disclosure, for example, an inert gas, preferably the carrier gas or dilution gas may be used as the purge gas.

Next, when necessary, a reaction gas is supplied. The reaction gas is not particularly limited as long as it is a reaction gas commonly used in the technical field to which the present invention pertains, and may preferably include nitriding gases such as nitrogen gas (N₂), hydrazine gas (N₂H₄), or a mixture of nitrogen gas and hydrogen gas, and reducing gases such as hydrogen gas (H₂).

The nitriding gas and the precursor compound adsorbed on the substrate react to form a nitride film.

The reducing gas and the precursor compound adsorbed on the substrate react to form a metal film.

Next, an inert gas is used to purge the unreacted residual reaction gas. Accordingly, not only the excessive reaction gas but also the by-products generated may be removed together.

In this way, for example, in the method of forming a thin film, a step of adsorbing a precursor compound on a substrate, a step of purging the unadsorbed precursor compound, a step of adsorbing a thin film forming material on the substrate, a step of purging the unadsorbed thin film forming material, a step of supplying a reaction gas when necessary, and a step of purging the residual reaction gas when necessary may be set as a unit cycle, and the unit cycle may be repeated to form a thin film having a desired thickness.

For example, the unit cycle may be repeated 1 to 99,999 times, preferably 10 to 1,000 times, more preferably 50 to 5,000 times, still more preferably 100 to 2,000 times. Within this range, the desired thin film properties may be well expressed.

In addition, the present invention provides a semiconductor substrate, and the semiconductor substrate is fabricated by the thin film formation method. In this case, the thickness uniformity of a thin film may be excellent, and the density and electrical properties thereof may be excellent.

The manufactured thin film may preferably have a thickness of 30 nm or less, a resistivity value of 5 to 2,000 μΩ·cm based on a thin film thickness of 10 nm, an impurity content of 10,000 ppm or less, and a step coverage of 90% or more. Within this range, the thin film has excellent performance as a diffusion barrier and has the excellent effect of metal wiring materials, without being limited thereto.

For example, the thin film may have a thickness of 0.1 to 30 nm, preferably 1 to 20 nm, more preferably 2 to 10 nm. Within this range, thin film properties may be excellent.

For example, the thin film may have a resistivity value of 0.1 to 400 μΩ·cm, preferably 0.1 to 200 μΩ·cm, more preferably 0.1 to 20 μΩ·cm based on a thin film thickness of nm. Within this range, thin film properties may be excellent.

The impurity content of the thin film may be preferably 10,000 ppm or less or 1 to 9,000 ppm, still more preferably 1 to 8,500 ppm, still more preferably 1 to 1,000 ppm. Within this range, the crystallinity of a thin film may be excellent, and the resistivity thereof may be improved. Here, the impurities remaining in the thin film are impurities retained in the thin film due to insufficient reduction of the metal precursor ligands, and may be, for example, carbon, nitrogen, oxygen, or halogen elements, and the lower the residual amount of impurities in the thin film, the better the film quality, which is desirable.

The thin film is characterized in that the content of thin film impurities derived from ligands is reduced to 1% or less, including carbon impurities, when measured by XPS.

For example, the thin film may have a step coverage of 90% or more, preferably 92% or more, more preferably 95% or more. Within this range, since even a thin film of complex structure may be easily deposited on a substrate, the thin film may be applied to next-generation semiconductor devices.

The manufactured thin film may preferably have a thickness of 20 nm or less, a carbon, nitrogen, oxygen, and halogen (impurities) content of 10,000 ppm or less based on a thin film thickness of 10 nm, and a step coverage of 90% or more. Within this range, the thin film may have excellent performance as a dielectric film or blocking film, without being limited thereto.

When crystallinity was measured using XRD, the crystallinity of the thin film may be improved.

The resistivity of the thin film may be improved.

Hereinafter, preferred examples and drawings are presented to help understand the present invention, but the following examples and drawings are only illustrative of the present invention, and it is obvious to those skilled in the art that various changes and modifications are possible within the scope and technical idea of the present invention. Such changes and modifications fall within the scope of the appended patent claims.

### EXAMPLES

### Example 1

An ALD deposition process was performed using 5 N HI as a thin film forming material and a BTBMMo precursor represented by Chemical Formula below as a precursor compound.

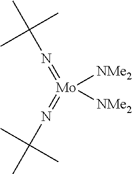

First, the prepared precursor compound was placed in a separate canister and supplied to a separate vaporizer heated to 150° C. at a flow rate of 0.1 g/min using a liquid mass flow controller (LMFC) at room temperature. Then, the BTBMMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Subsequently, the prepared thin film forming material was placed in a canister and supplied into the chamber at a flow rate of 1000 sccm at room temperature using a mass flow controller (MFC). The thin film forming material vaporized into a vapor phase in the vaporizer was introduced into the substrate-loaded deposition chamber for 2 seconds to perform a reduction reaction. Then, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Example 2

An ALD deposition process was performed using 5 N HI as a thin film forming material, NH₃ as a reaction gas, and a BTBMMo precursor represented by Chemical Formula below as a precursor compound.

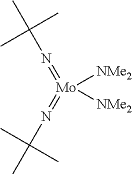

First, the prepared precursor compound was placed in a separate canister and supplied to a separate vaporizer heated to 150° C. at a flow rate of 0.1 g/min using a liquid mass flow controller (LMFC) at room temperature. Then, the BTBMMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Subsequently, the prepared HI thin film forming material was placed in a canister and supplied into the chamber at a flow rate of 1000 sccm at room temperature using a mass forming material vaporized into a vapor phase in the vaporizer into the substrate-loaded deposition chamber for 2 seconds to perform a catalytic reaction, argon gas was supplied at 5000 sccm for 10 seconds to perform argon purging. Then, after supplying NH₃ reaction gas into the chamber at a flow rate of 1000 sccm, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Example 3

An ALD deposition process was performed using 5 N HI as a thin film forming material and a BTBTBMo precursor represented by Chemical Formula below as a precursor compound.

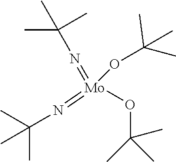

First, the prepared precursor compound was placed in a separate canister and supplied to a separate vaporizer heated to 150° C. at a flow rate of 0.1 g/min using a liquid mass flow controller (LMFC) at room temperature. After introducing the BTBTBMo precursor vaporized into a vapor phase in the vaporizer into the deposition chamber for 3 seconds, argon gas was supplied at 5000 sccm for 10 seconds to perform argon purging. At this time, the pressure inside the reaction chamber was controlled to 2.5 Torr.

Subsequently, the prepared thin film forming material was placed in a canister and supplied into the chamber at a flow rate of 1000 sccm at room temperature using a mass flow controller (MFC). The thin film forming material vaporized into a vapor phase in the vaporizer was introduced into the substrate-loaded deposition chamber for 2 seconds to perform a reduction reaction. Then, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Example 4

An ALD deposition process was performed using 5 N HI as a thin film forming material, NH₃ as a reaction gas, and a BTBTBMo precursor represented by Chemical Formula below as a precursor compound.

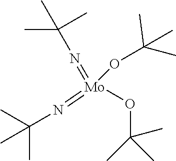

First, the prepared precursor compound was placed in a separate canister and supplied to a separate vaporizer heated to 150° C. at a flow rate of 0.1 g/min using a liquid mass flow controller (LMFC) at room temperature. After introducing the BTBTBMo precursor vaporized into a vapor phase in the vaporizer into the deposition chamber for 3 seconds, argon gas was supplied at 5000 sccm for 10 seconds to perform argon purging. At this time, the pressure inside the reaction chamber was controlled to 2.5 Torr.

Subsequently, the prepared HI thin film forming material was placed in a canister and supplied into the chamber at a flow rate of 1000 sccm at room temperature using a mass flow controller (MFC). After introducing the thin film forming material vaporized into a vapor phase in the vaporizer into the substrate-loaded deposition chamber for 2 seconds to perform a catalytic reaction, argon gas was supplied at 5000 sccm for 10 seconds to perform argon purging. Then, after supplying NH₃ reaction gas into the chamber at a flow rate of 1000 sccm, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Example 5

An ALD deposition process was performed using 5 N HI as a thin film forming material and an Mo(CO)₆ precursor represented by Chemical Formula below as a precursor compound.

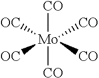

First, the prepared precursor compound was placed in a separate canister, heated to 50° C., and then the Mo(CO)₆ precursor was introduced into the deposition chamber for 3 seconds with an Ar carrier at 50 sccm. Then, argon gas was supplied at 5000 sccm for 10 seconds to perform argon purging. At this time, the pressure inside the reaction chamber was controlled to 2.5 Torr.

Subsequently, the prepared thin film forming material was placed in a canister and supplied into the chamber at a flow rate of 1000 sccm at room temperature using a mass flow controller (MFC). The thin film forming material vaporized into a vapor phase in the vaporizer was introduced into the substrate-loaded deposition chamber for 2 seconds to perform a reduction reaction. Then, argon gas was supplied at 5000 sccm for 10 seconds to perform argon purging. At this time, the pressure inside the reaction chamber was controlled to 2.5 Torr. The deposition temperature was maintained at 375° C., and such a process was repeated 50 to 200 times to form a 10 nm thick self-limiting atomic layer thin film.

Using an ellipsometer which is a device capable of measuring optical properties such as thickness and refractive index of the thin film by using the polarization characteristics of light for the manufactured thin film (Mo metal film), the thickness of the thin film deposited per cycle was calculated by dividing the measured thickness of the thin film by the number of cycles, and the result was 10 nm. Sheet resistance was measured using the four-probe measurement method, and the resistivity value was calculated by using the measured thickness. The crystallinity of the Mo thin film was confirmed through XRD analysis.

### Example 6

An ALD deposition process was performed using 5 N HI as a thin film forming material and an Mo(tol)₂ precursor represented by Chemical Formula below as a precursor compound.

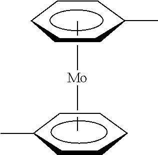

First, the prepared precursor compound was placed in a separate canister, heated to 130° C., and then the Mo(tol)₂ precursor was introduced into the deposition chamber for 10 seconds with an Ar carrier at 50 sccm. Then, argon gas was supplied at 5000 sccm for 10 seconds to perform argon purging. At this time, the pressure inside the reaction chamber was controlled to 2.5 Torr.

Subsequently, the prepared thin film forming material was placed in a canister and supplied into the chamber at a flow rate of 1000 sccm at room temperature using a mass flow controller (MFC). The thin film forming material vaporized into a vapor phase in the vaporizer was introduced into the substrate-loaded deposition chamber for 2 seconds to perform a reduction reaction. Then, argon gas was supplied at 5000 sccm for 10 seconds to perform argon purging. At this time, the pressure inside the reaction chamber was controlled to 2.5 Torr. The deposition temperature was maintained at 250° C., and such a process was repeated 30 to 300 times to form a 10 nm thick self-limiting atomic layer thin film.

Using an ellipsometer which is a device capable of measuring optical properties such as thickness and refractive index of the thin film by using the polarization characteristics of light for the manufactured thin film (Mo metal film), the thickness of the thin film deposited per cycle was calculated by dividing the measured thickness of the thin film by the number of cycles, and the result was 10 nm. Sheet resistance was measured using the four-probe measurement method, and the resistivity value was calculated by using the measured thickness.

### Example 7

An ALD deposition process was performed using 5 N HI and I-7 of 99% as thin film forming materials and an MoCl₅ precursor represented by Chemical Formula below as a precursor compound.

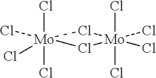

First, the prepared precursor compound was placed in a separate canister, heated to 140° C., and then the MoCl₅ precursor was introduced into the deposition chamber for 5 seconds with an Ar carrier at 100 sccm, and then argon gas was supplied at 5000 sccm for 10 seconds to perform argon purging. At this time, the pressure in the reaction chamber was controlled to 5.0 Torr.

Subsequently, the prepared thin film forming material was placed in a canister and supplied into the chamber at a flow rate of 1000 sccm at room temperature using a mass flow controller (MFC). The thin film forming material vaporized into a vapor phase in the vaporizer was introduced into the substrate-loaded deposition chamber for 2 seconds to perform a reduction reaction. Then, argon gas was supplied at 5000 sccm for 10 seconds to perform argon purging. At this time, the pressure in the reaction chamber was controlled to 5.0 Torr. The deposition temperature was maintained at 400 to 600° C., and such a process was repeated 30 to 300 times to form a 10 nm thick self-limiting atomic layer thin film.

### Example 8

The bond dissociation energy of the thin film forming material and the metal precursor of the present invention is an important factor in reducing the precursor at a low temperature. For the calculation of bond dissociation energy, the computational simulation program Gaussian 16 was used, the computational method was DFT-D3/B3LYP, the basis set for iodine and the central metal (e.g., Mo) was LanL2DZ, and the basis set for other elements was 6−31+G (d, p).

In addition, the reaction activation energy between Mo(CO)₆ or (EtCp)Mo(CO)₂ (NO) precursor and the thin film forming material was also calculated in the same manner. At this time, the transition state method was DFT/TS-Berny and the intrinsic reaction coordinate was 40 pts.

### Example 9

Using 5 N HI as a thin film forming material and MOO₂Cl₂, MOCl₅, BTBMMO, Mo(CO)₆, Mo(Tol)₂, (CP)Mo(NO)(CO)₂, and (Cycloheptatriene)Mo(CO)₃ precursors represented by Chemical Formulas below as precursor compounds, to compare the low-temperature reduction process effect according to the ligand bond dissociation energy, an ALD deposition process was performed at 250 to 400° C.

First, the prepared precursor compounds were each placed in a separate canister and introduced into the deposition chamber under vapor pressure conditions of 0.1 to 1 Torr, and then argon gas was supplied at 5000 sccm for 10 seconds to perform argon purging. At this time, the pressure in the reaction chamber was controlled to 5.0 Torr.

Subsequently, the prepared thin film forming material was placed in a canister and supplied into the chamber at a flow rate of 1000 sccm at room temperature using a mass flow controller (MFC). After introducing the thin film forming material vaporized into a vapor phase in the vaporizer into the substrate-loaded deposition chamber for 3 seconds to perform a reduction reaction, argon gas was supplied at 5000 sccm for 10 seconds to perform argon purging. At this time, the pressure in the reaction chamber was controlled to 5.0 Torr. The process was repeated 30 to 300 times to form a 10 nm thick self-limiting atomic layer thin film.

### Example 10

As the thin film forming material, I-1, 1-3, I-5, I-7, I-8, I-10, and I-12 having a purity of 99% or more among the substances whose bond dissociation energy was calculated in Table 5 were used, NH₃ was used as a reaction material for the nitriding process, and TiCl₄ precursor was used as a precursor compound. In this condition, an ALD deposition process was performed.

First, the prepared precursor compound was placed in a separate canister, heated to 50° C., and then the TiCl₄ precursor was introduced into the deposition chamber for 3 seconds with an Ar carrier at 100 sccm, followed by supplying argon gas at 3000 sccm for 5 seconds to perform argon purging. At this time, the pressure in the reaction chamber was controlled to 2.0 Torr.

Subsequently, the prepared thin film forming material was placed in a canister and supplied into the chamber at a flow rate of 10 sccm at room temperature using a mass flow controller (MFC). After introducing the thin film forming material vaporized into a vapor phase in the vaporizer into the substrate-loaded deposition chamber for 3 seconds to perform a reduction reaction, argon gas was supplied at 3000 sccm for 10 seconds to perform argon purging. At this time, the pressure in the reaction chamber was controlled to 2.0 Torr.

Subsequently, NH₃ was supplied into the chamber at 1000 sccm as a reaction gas. The deposition temperature was maintained at 550° C., and the process was repeated 50 to 150 times to form a 10 nm thick self-limiting atomic layer thin film.

### COMPARATIVE EXAMPLES

### Comparative Example 1

An ALD deposition process was performed using NH₃ as a thin film forming material and a BTBMMo precursor represented by Chemical Formula below as a precursor compound.

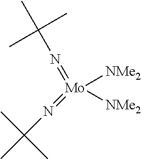

First, the prepared precursor compound was placed in a separate canister and supplied to a separate vaporizer heated to 150° C. at a flow rate of 0.1 g/min using a liquid mass flow controller (LMFC) at room temperature. Then, the BTBMMo precursor vaporized in a vapor phase in the vaporizer was injected into the deposition chamber for 3 seconds, and then argon gas was supplied at 5000 sccm for 10 seconds to perform argon purging. At this time, the pressure inside the reaction chamber was controlled to 2.5 Torr.

Subsequently, the prepared thin film forming material NH₃ was supplied into the chamber at a flow rate of 1,000 sccm. The thin film forming material vaporized into a vapor phase in the vaporizer was introduced into the substrate-loaded deposition chamber for 2 seconds to perform a reduction reaction. Then, argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Comparative Example 2

An ALD deposition process was performed using NH₃ as a reaction gas and a BTBTBMo precursor represented by Chemical Formula below as a precursor compound.

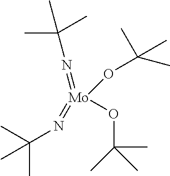

First, the prepared precursor compound was placed in a separate canister and supplied to a separate vaporizer heated to 150° C. at a flow rate of 0.1 g/min using a liquid mass flow controller (LMFC) at room temperature. After introducing the BTBTBMo precursor vaporized into a vapor phase in the vaporizer into the deposition chamber for 3 seconds, argon gas was supplied at 5000 sccm for 10 seconds to perform argon purging. At this time, the pressure inside the reaction chamber was controlled to 2.5 Torr.

Subsequently, the prepared reaction gas NH₃ Was supplied into the chamber at a flow rate of 1,000 sccm. The reaction gas vaporized into a vapor phase in the vaporizer was introduced into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. This process was repeated 200 to 400 times while maintaining the deposition temperature at 350° C. to form a self-limiting atomic layer thin film with a thickness of 10 nm.

Using an ellipsometer which is a device capable of measuring optical properties such as thickness and refractive index of the thin film by using the polarization characteristics of light for the manufactured thin film (MON metal film), the thickness of the thin film deposited per cycle was calculated by dividing the measured thickness of the thin film by the number of cycles, and the result was 10 nm. The component analysis of the thin film was performed through AES and SIMS analyses. Then, sheet resistance was measured using the four-probe measurement method, and the resistivity value was calculated by using the measured thickness.

### Comparative Example 3

An ALD deposition process was performed using NH₃ as a reaction gas and an Mo(CO)₆ precursor represented by Chemical Formula below as a precursor compound.

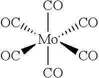

First, the prepared precursor compound was placed in a separate canister, heated to 50° C., and then the Mo(CO)₆ precursor was introduced into the deposition chamber for 3 seconds with an Ar carrier at 50 sccm. Then, argon gas was supplied at 5000 sccm for 10 seconds to perform argon purging. At this time, the pressure inside the reaction chamber was controlled to 2.5 Torr.

Subsequently, the prepared reaction gas NH₃ was supplied into the chamber at a flow rate of 1,000 sccm. The reaction gas vaporized into a vapor phase in the vaporizer was introduced into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. The deposition temperature was maintained at 375° C., and such a process was repeated 50 to 200 times to form a 10 nm thick self-limiting atomic layer thin film.

Using an ellipsometer which is a device capable of measuring optical properties such as thickness and refractive index of the thin film by using the polarization characteristics of light for the manufactured thin film (Mo metal film), the thickness of the thin film deposited per cycle was calculated by dividing the measured thickness of the thin film by the number of cycles, and the result was 10 nm. Sheet resistance was measured using the four-probe measurement method, and the resistivity value was calculated by using the measured thickness. The crystallinity of the Mo thin film was confirmed through XRD analysis.

### Comparative Example 4

An ALD deposition process was performed using NH₃ as a reaction gas and an Mo(tol) 2 precursor represented by Chemical Formula below as a precursor compound.

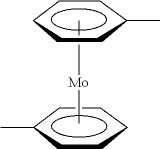

First, the prepared precursor compound was placed in a separate canister, heated to 130° C., and then the Mo(tol)₂ precursor was introduced into the deposition chamber for 10 seconds with an Ar carrier at 50 sccm. Then, argon gas was supplied at 5000 sccm for 10 seconds to perform argon purging. At this time, the pressure inside the reaction chamber was controlled to 2.5 Torr.

Subsequently, the prepared reaction gas NH₃ was supplied into the chamber at a flow rate of 1,000 sccm. The reaction gas vaporized into a vapor phase in the vaporizer was introduced into the substrate-loaded deposition chamber for 2 seconds to perform a reduction reaction, and then argon gas was supplied at 5000 sccm for 10 seconds to perform argon purging. At this time, the pressure inside the reaction chamber was controlled to 2.5 Torr. The deposition temperatures were maintained at 250° C. and 300° C., respectively, and such a process was repeated 30 to 300 times to form a 10 nm thick self-limiting atomic layer thin film.

Using an ellipsometer which is a device capable of measuring optical properties such as thickness and refractive index of the thin film by using the polarization characteristics of light for the manufactured thin film (Mo metal film), the thickness of the thin film deposited per cycle was calculated by dividing the measured thickness of the thin film by the number of cycles, and the result was 10 nm. Sheet resistance was measured using the four-probe measurement method, and the resistivity value was calculated by using the measured thickness.

### Comparative Example 5

The bond dissociation energy of the thin film forming material and the metal precursor of the present invention is an important factor in reducing the precursor at a low temperature. For the calculation of bond dissociation energy, the computational simulation program Gaussian 16 was used, the computational method was DFT-D3/B3LYP, the basis set for iodine and the central metal (e.g., Mo) was LanL2DZ, and the basis set for other elements was 6−31+G (d, p).

In addition, the reaction activation energy between the Mo(CO)₆, (EtCp)Mo(CO)₂ (NO) precursor and H₂ was also calculated in the same manner. At this time, the transition state method was DFT/TS-Berny and the intrinsic reaction coordinate was 40 pts.

### Comparative Example 6

An ALD deposition process was performed using I-1 of 99% as a thin film forming material and an MoCl₅ precursor represented by Chemical Formula below as a precursor compound.

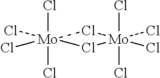

First, the prepared precursor compound was placed in a separate canister, heated to 140° C., and then the MoCl₅ precursor was introduced into the deposition chamber for 5 seconds with an Ar carrier at 100 sccm, and then argon gas was supplied at 5000 sccm for 10 seconds to perform argon purging. At this time, the pressure in the reaction chamber was controlled to 5.0 Torr.

Subsequently, the prepared thin film forming material was placed in a canister and supplied into the chamber at a flow rate of 1000 sccm at room temperature using a mass flow controller (MFC). The thin film forming material vaporized into a vapor phase in the vaporizer was introduced into the substrate-loaded deposition chamber for 2 seconds to perform a reduction reaction. Then, argon gas was supplied at 5000 sccm for 10 seconds to perform argon purging. At this time, the pressure in the reaction chamber was controlled to 5.0 Torr. The deposition temperature was maintained at 400 to 600° C., and such a process was repeated 30 to 300 times to form a 10 nm thick self-limiting atomic layer thin film.

### Comparative Example 7

An ALD deposition process was performed using NH₃ as a reaction material for a nitriding process and TiCl₄ precursor as a precursor compound.

First, the prepared precursor compound was placed in a separate canister, heated to 50° C., and then the TiCl₄ precursor was introduced into the deposition chamber for 3 seconds with an Ar carrier at 100 sccm, followed by supplying argon gas at 3000 sccm for 5 seconds to perform argon purging. At this time, the pressure in the reaction chamber was controlled to 2.0 Torr.

Subsequently, NH₃ was supplied into the chamber at 1000 sccm as a reaction gas. The deposition temperature was maintained at 550° C., and the process was repeated 50 to 150 times to form a 10 nm thick self-limiting atomic layer thin film.

### Test Examples

For each of the thin films of Examples 1 to 10 and Comparative Examples 1 to 7, the impurity content, the types and contents of elements constituting the material surface, the deposition rate, the crystal structure, and the orientation were analyzed and confirmed in the following manner.
SIMS (Secondary-ion mass spectrometry) C impurities: By sputtering the thin film axially with ion sputtering, the C impurity value was confirmed from the SIMS graph by considering the C impurity content (counts) at a sputtering time of 50 seconds, when surface contamination of a substrate was minimal.
AES (Auger electron spectroscopy): The types and contents of elements constituting the material surface were analyzed by irradiating the material surface with a focused electron beam and measuring the energy of the emitted Auger electrons.
Deposition rate (GPC) measurement: For each of the thin films of Examples 1 to 6 and Comparative Examples 1 to 4, the deposition rate (GPC) was measured in the following manner. Specifically, the deposition rate of thin films having a thickness of 3 to 30 nm was measured using an ellipsometer, and the unit of Å/cycle was used.
Grazing-incidence angle (incident angle, θ=3°) X-ray diffractometry: To confirm information such as crystal structure and orientation, diffraction analysis of the surface was performed using Cu-Kα X-ray.

TABLE 1

| | | Precursor | | |
|---|---|---|---|---|
| | | BTBMMo | | |
| | | Comparative | | |
| Subjects | | Example 1 | Example 1 | Example 2 |
| Thin film forming | | NH₃ | HI | HI → NH₃ |
| material | | | | |
| Process temperature | | 350° C. | | |
| Deposition rate | | 0.7 | 0.3 | 0.3 |
| (Å/cycle) | | | | |
| Resistivity (μΩ · cm) | | ~1600 | 1672 | 1667 |
| Mo/N (AES) | | 1.3 | 0.9 | 0.9 |
| C impurities (AES) | | 28 | 0 | 0 |
| O impurities (AES) | | 9 | 13 | 10 |
| Density (g/cm³) | | 6.0 | 6.7 | 6.8 |
| SIMS | C⁻ | 46762 | — | 4054 |
| | CN⁻ | 10996 | — | 1177 |

As shown in Table 1, according to the present invention, when a single HI thin film forming material process or a combined process of an HI thin film forming material and NH₃ reaction gas is used, it can be confirmed that the amount of C impurities generated when the NH₃ reducing agent is used alone is significantly reduced. In addition, as shown in Examples 1 and 2, it was confirmed from the AES analysis results that C impurities were reduced to 0% during thin film formation, and according to the SIMS results, the number of detected C ions was confirmed to be reduced by 91% or more.

In addition, since the thin film density increased from 6.0 to 6.8, it can be seen that a very high-quality MON thin film was formed.

TABLE 2

| | | Precursor | | |
|---|---|---|---|---|
| | | BTBTBMo | | |
| | | Comparative | | |
| Subjects | | Example 2 | Example 3 | Example 4 |
| Thin film forming | | NH₃ | HI | HI → NH₃ |
| material | | | | |
| Process temperature | | 350° C. | | |
| Deposition rate | | ~0.55 | 0.3 | 0.5 |
| (Å/cycle) | | | | |
| Resistivity (μΩ · cm) | | ~2500 | ~1800 | ~1800 |
| Mo/N (AES) | | 0.7 | 1.0 | 0.9 |
| C impurities (AES) | | 0 | 0 | 0 |
| O impurities (AES) | | 21 | 18 | 12 |
| Density (g/cm³) | | 6.83 | 6.80 | 6.90 |
| SIMS | C⁻ | 11774 | 2934 | 4534 |
| | CN⁻ | 2817 | 708 | 1055 |

As shown in Table 2, according to the present invention, when a single HI thin film forming material process or a combined process of an HI thin film forming material and NH₃ is used, compared with the case of using the NH₃ reaction gas alone, the resistivity of the formed thin 1 was significantly reduced, and the C impurities were shown to decrease most effectively when only the HI thin film forming material was used, in the order of Comparative Example 2>Example 4>Example 3.

TABLE 3

Precursor
Mo(CO)₆

| | Comparative | |
|---|---|---|
| Subjects | Example 3 | Example 5 |
| Thin film forming material | NH₃ | HI |

| | |
|---|---|
| Process temperature (° C.) | 375 |

| | | |
|---|---|---|
| Deposition rate (Å/cycle) | ~0.6 | ~1.8 |
| Resistivity (μΩ · cm) | 415 | 58 |

As shown in Table 3, according to the present invention, when the HI thin film forming material is used, the resistivity of the formed thin film is significantly reduced compared with the case of using only the NH₃ reaction gas, and the deposition rate increased more than threefold. In particular, XRD analysis was performed according to process temperature, and the results are shown in FIG. 2. FIG. 2 is an XRD analysis graph according to process temperature between Example 5 of the present invention and Comparative Example 3.

As shown in FIG. 2 below, Example 5 shows that a pure Mo metal thin film was formed.

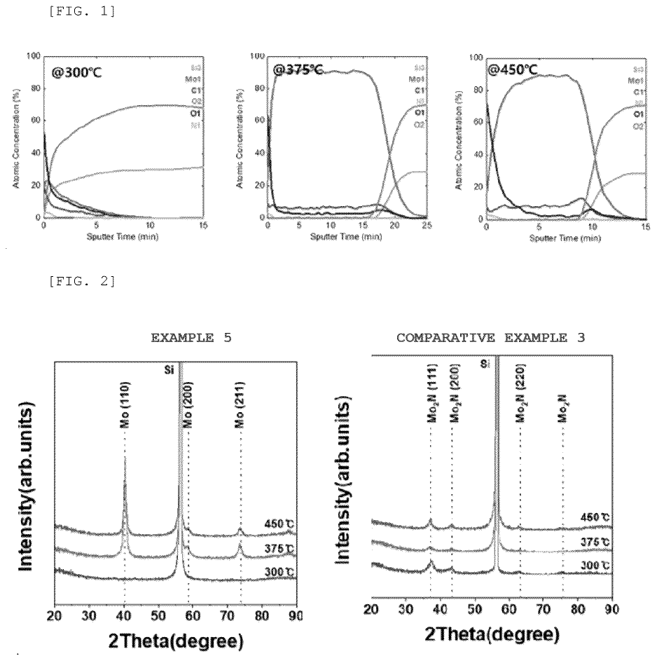

In addition, the AES analysis results according to temperature for Example 5 are shown in FIG. 1 below.

FIG. 1 is a graph showing the AES analysis results according to temperature in Example 5 of the present invention. As shown in FIG. 1 below, the types and content variations of the constituent elements according to process temperature were confirmed.

TABLE 4

| | Precursor | |
|---|---|---|
| | Mo(tol)₂ | |
| | Comparative | |
| Subjects | Example 4 | Example 6 |

| | | | |
|---|---|---|---|
| Thin film forming | NH₃ | HI | HI |
| material | | | |
| Process temperature | 250 | 250 | 300 |
| (° C.) | | | |
| Deposition rate | 0.37 | 0.83 | ~2.5 |
| (Å/cycle) | | | |
| Resistivity (μΩ · cm) | 22800 | 10900 | 800 |

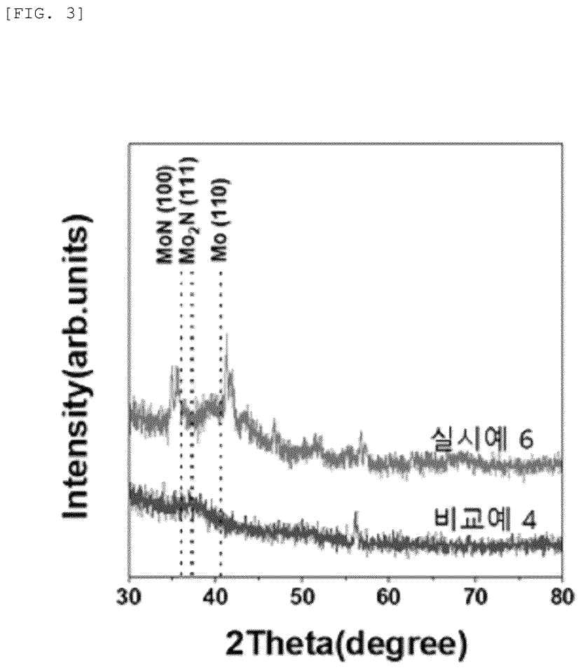

As shown in Table 4, according to the present invention, when the HI thin film forming material is used, the resistivity of the formed thin film is significantly reduced compared with the case of using only the NH₃ reaction gas, and the deposition rate increased more than twofold. In particular, XRD analysis was performed, and the results are shown in FIG. 3. FIG. 3 is an XRD analysis graph between Example 6 of the present invention and Comparative Example 4.

As shown in FIG. 3 below, it can be seen that a pure Mo metal thin film was partially formed in Example 6.

TABLE 5

| | Precursor | | | |
|---|---|---|---|---|
| | Mo(Cl)₅ | | | |
| | | | | Comparative |
| Subjects | Example 7 | | | Example 6 |
| Thin film forming | HI | HI | I-7 | I-1 |
| material | | | | |
| Bond dissociation | 314.18 | 314.18 | 236.38 | 250.15 |
| energy (KJ/mol) | | | | |
| Process | 400 | 500 | 500 | 500 |
| temperature (° C.) | | | | |
| Deposition rate | 1.7 | 1.7 | 1.7 | 1.8 |
| (Å/cycle) | | | | |
| Resistivity | 52 | 13 | 14 | 151 |
| (μΩ · cm) | | | | |
| Thin film type | Mo | Mo | Mo | Mo + C |

As shown in Table 5, according to the present invention, when the HI thin film forming material is used, it can be seen that a Mo metal thin film with low resistivity was formed even at a low temperature of 400° C. In addition, it was found that in the case of iodine bonded to carbon, when I-7 having a low bond dissociation energy was used, an Mo thin film was formed without carbon impurities. However, in the case of I-1 having a strong carbon-iodine bond of 250 kJ/mol, not only did the resistivity increase more than tenfold, but carbon impurities were also present in the thin film. The reason for the increase in resistivity is due to carbon, since carbon acts as an impurity inside the thin film. The mechanism of residual thin film impurities is that when the bond dissociation energy of carbon and iodine is high, the iodine bond does not dissociate, or the dissociated carbon molecules strongly bond to the substrate surface and are not desorbed.

In Example 8, the results of calculating the bond dissociation energy of carbon- or hydrogen-containing compounds bonded with iodine are shown in Table 6 below.

TABLE 6

| | Structure | BDE (C-1) (kJ/mol) |
|---|---|---|
| I-1 | 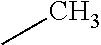 | 250.15 |
| I-2 | 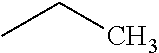 | 247.37 |
| I-3 | 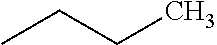 | 250.08 |
| I-4 | 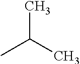 | 243.02 |
| I-5 | 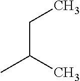 | 244.65 |
| I-6 | 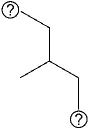 [symbol] | 247.09 |
| I-7 | 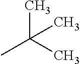 | 236.38 |
| I-8 | 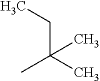 | 239.29 |
| I-9 | 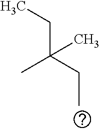 | 241.02 |
| I-10 | 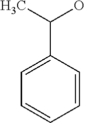 | 194.21 |
| I-11 | 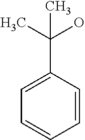 | 186.78 |
| I-12 | HI | 314.18 |
| I-12 | 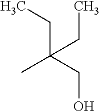 | 241.36 |
| I-13 | 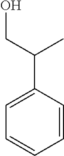 | 197.09 |
| I-14 | ICl | 150.26 |
| I-15 | IBr | 134.59 |
| I-16 | ICl₃ | 68.23 |

[symbol]

indicates data missing or illegible when filed

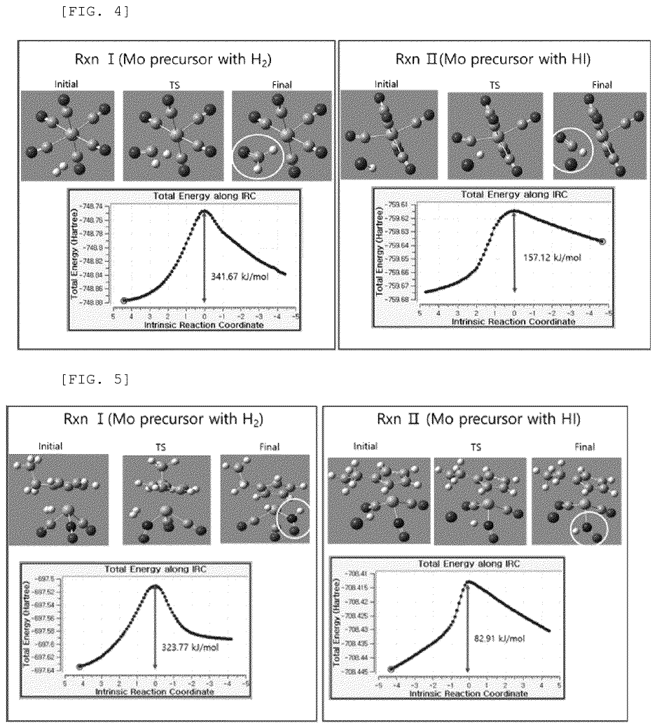

In addition, in Example 8 and Comparative Example 5, the reaction activation energy required to reduce the CO ligand of the Mo(CO)₆ precursor and the NO ligand of the (EtCp)Mo(CO)₂ (NO) precursor was compared for H₂ and HI, and the results are shown in FIGS. 4 and 5 below.

As shown in FIGS. 4 and 5 below, in the Mo(CO)₆ precursor, the energy required to reduce the CO ligand using H₂ was 341.67 kJ/mol, whereas when HI was used, it was confirmed to be a much lower activation energy of 157.12 kJ/mol. This result demonstrates that reduction may be achieved at even lower process temperatures without C and O impurities.

In the (EtCp)Mo(CO)₂ (NO) precursor, the energy required to reduce the NO ligand using H₂ was 323.77 kJ/mol, whereas when HI was used, it was confirmed to be a much lower activation energy of 82.91 kJ/mol. This result demonstrates that reduction may be achieved at even lower process temperatures without N and O impurities.

The bond dissociation energy of Mo precursors suitable for low-temperature processes is shown in Table 7 below.

TABLE 7

| | | | | Process temperature |
|---|---|---|---|---|
| | | | Mo-ligand | of 400° C. or lower |
| # | Chemical Structure | Ligands | Binding energy | Reduction reaction |
| 1 | MoO₂Cl₂ | Oxo | 859.2 KJ/mol | X |
| | | Chloride | 367.8 KJ/mol | X |
| 2 | MoCl₃ | chloride | 248.6 KJ/mol | O |
| 3 | 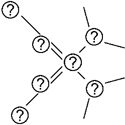 | Imido Amide | 631.9 KJ/mol 297.76 KJ/mol | X O |
| 4 | 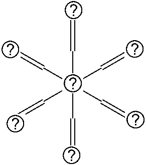 | Carbonyl | 163.3 KJ/mol | O |
| 5 | 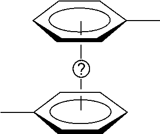 | Toluene | 283.7 KJ/mol | O |
| 6 | [symbol] | Cyclopentadienyl Nitrosyl Carbonyl | 431.74 KJ/mol 321.26 KJ/mol 208.2 KJ/mol | X O O |
| 7 | [symbol] | Cycloheptatriene CO | 431.74 KJ/mol 208.2 KJ/mol | X O |

[symbol]

indicates data missing or illegible when filed

As shown in Table 7, it was confirmed that when the bond dissociation energy between Mo and the ligands bonded thereto is 350 kJ/mol or less, reduction occurs at 400° C. or lower.

Table 8 below shows the resistivity results according to the bond dissociation energy among the inventive materials used to reduce the reaction activation energy between TiCl₄ and NH₃ reaction gas during TiN thin film formation.

TABLE 8

| | | | Bond | | | Resistivity Change |
|---|---|---|---|---|---|---|
| | TiN process | | Dissociation | | Average Resistivity | Compared to |
| # | @ 550° C. | Chemical Structure | Energy | GPC (Å/cycle) | (μΩ•cm) | No-Catalyst |
| 1 | Catalyst-free | — | — | 0.38 | 200 | |
| 2 | I-7 | 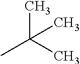 | 236.38 | 0.57 | 113 | Resistivity Improvement |
| 3 | I-8 | 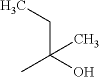 | 239.29 | 0.58 | 117 | Resistivity Improvement |
| 4 | I-12 | HI | 314.18 | 0.72 | 112 | Resistivity Improvement |
| 5 | I-10 | 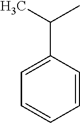 | 194.21 | 0.65 | 110 | Resistivity Improvement |
| 6 | I-3 | 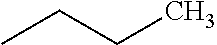 | 250.8 | 0.6 | 574 | Resistivity Deterioration |
| 7 | I-5 | 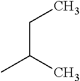 | 244.65 | 0.53 | 392 | Resistivity Deterioration |
| 8 | I-1 | 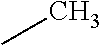 | 250.15 | 0.33 | 752 | Resistivity Deterioration |

As shown in Table 8, except for I-12, which has no carbon-iodine bond, in the case of iodine bonded to carbon, it was confirmed that only the materials having 242 kJ/mol or less not only improved the deposition rate but also exhibited an effect of improving resistivity.

In particular, it was confirmed that as the bond dissociation energy between carbon and iodine increases, the extent of resistivity deterioration also increases.

In conclusion, by using a predetermined thin film forming material capable of performing a catalytic reaction or reduction reaction for a precursor compound adsorbed on a substrate loaded into a chamber at a relatively low process temperature at which a precursor is not thermally decomposed, it was confirmed to be suitable for improving film quality such as electrical characteristics and crystallinity while preventing and suppressing the introduction of thin film impurities caused by ligands such as carbon.

1. A thin film forming material having a bond dissociation energy of 242 kJ/mol or less and 290 kJ/mol or more with hydrogen (H), carbon (C), or a halogen element (F, Cl, or Br) bonded to iodine as calculated using a Gaussian 16 program (basis set of DFT-D3/B3LYP (iodine: LanL2DZ, carbon, hydrogen element: 6−31+G(d·p)).

2. The thin film forming material according to claim 1, wherein the thin film forming material is a material that forms a metal thin film or a metal nitride thin film through a reduction or catalytic reaction, and comprises a compound in which iodine (I) is bonded to hydrogen (H), carbon (C), or a halogen element (F, Cl, or Br).

3. The thin film forming material according to claim 1, wherein the thin film forming material comprises one or more selected from compounds represented by Chemical Formulas 1-1 to 1-11 below.

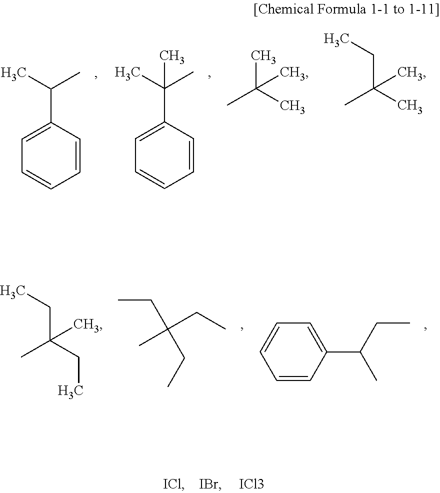

4. The thin film forming material according to claim 1, wherein the thin film forming material is 3 N to 15 N hydrogen iodide, a gas mixture containing 1 to 99% by weight of 3 N to 15 N hydrogen iodide and a residual amount (amount that makes a total amount 100% by weight) of an inert gas, or an aqueous solution mixture containing 0.5 to 70% by weight of 3 N to 15 N hydrogen iodide and a residual amount (amount that makes a total amount 100% by weight) of water,
wherein the inert gas is nitrogen, helium, or argon having a purity of 4 N to 9 N.

5. A method of forming a thin film using the thin film forming material according to claim 1.

6. The method according to claim 5, comprising injecting a precursor compound into a chamber to adsorb the precursor compound onto a surface of a substrate; and injecting the thin film forming material into the chamber and forming a metal thin film or a metal nitride thin film through a reduction reaction.

7. The method according to claim 5, comprising injecting a precursor compound into a chamber to adsorb the precursor compound onto a surface of a substrate; injecting the thin film forming material into the chamber to reduce reaction activation energy with a reaction gas; and supplying a reaction gas into the chamber and forming a metal thin film or a metal nitride thin film through a reduction reaction.

8. The method according to claim 6, wherein each step comprises purging the inside of the chamber with a purge gas.

9. The method according to claim 6, wherein the chamber is an ALD chamber, a CVD chamber, a PEALD chamber, or a PECVD chamber.

10. The method according to claim 5, wherein the thin film is a laminated film containing one or more selected from the group consisting of Al, Cu, Au, Mo, Ag, W, Pt, Ta, Co, Ru, and Ti.

11. The method according to claim 5, wherein the thin film is a metal thin film or metal nitride thin film having a resistivity of 5μΩ·cm to 1000μΩ·cm.

12. The method according to claim 5, wherein the precursor compound is a molecule having Mo as a central metal atom (M) and one or more ligands selected from C, N, O, H, and X (halogen), and is a compound having a bond dissociation energy of 350 kJ/mol or less between the central metal atom and the ligand to reduce the Mo metal even at a low process temperature of 400° C. or lower, as calculated using a Gaussian 16 program (basis set of DFT-D3/B3LYP (central metal, iodine: LanL2DZ, C, N, O, H, X: 6−31+G (d·p)).

13. The method according to claim 6, wherein the substrate loaded into the chamber is heated to 100 to 800° C.

14. The method according to claim 5, wherein the thin film is an aluminum metal film, a copper metal film, a gold metal film, a molybdenum metal film, a silver metal film, a tungsten metal film, a platinum metal film, a tantalum metal film, a cobalt metal film, a ruthenium metal film, a rhodium metal film, a titanium metal film, an aluminum nitride film, a copper nitride film, a gold nitride film, a molybdenum nitride film, a silver nitride film, a tungsten nitride film, a platinum nitride film, a tantalum nitride film, a cobalt nitride film, a ruthenium nitride film, a rhodium nitride film, or a titanium nitride film.

15. A semiconductor substrate comprising the thin film manufactured using the method according to claim 6.

16. A semiconductor device comprising the semiconductor substrate according to claim 15.
